(19) United States
(12) Patent Application Publication
(10) Pub. No.: US 2006/0270070 A1
(43) Pub. Date: Nov. 30, 2006

(54) Electronic device, electronic device producing method, thermal head, and thermal head producing method

(75) Inventors: Tomoyoshi Nishimura, Saitama (JP); Koji Kato, Kagoshima (JP)

Correspondence Address: SUGHRUE MION, PLLC, 2100 PENNSYLVANIA AVENUE, N.W., SUITE 800, WASHINGTON, DC, 20037, US

(73) Assignees: FUJI PHOTO FILM CO., LTD.; KYOCERA CORPORATION

(21) Appl. No.: 11/439,262

(22) Filed: May 24, 2006

(30) Foreign Application Priority Data
May 24, 2005 (JP) 2005-151391

(51) Int. Cl. H01L 21/00

(52) U.S. Cl. 438/11

(57) ABSTRACT

A thermal head includes a substrate, a partial glaze, a resistor layer and an aluminum electrode layer overlaid on one another sequentially. A protective layer protects the electrode layer and the resistor layer. The substrate is obtained by cutting a plate workpiece along a cut line for the electrode layer and the resistor layer. In a thermal head producing method, a spot pattern is formed on the electrode layer. The spot pattern includes plural spot regions arranged on the plate workpiece in a two-dimensional manner. The spot pattern is cut along the cut line to cause the electrode layer to appear on a cut end face of the cut line. Preferably, the spot pattern extends toward the circuit pattern from the cut end face at a predetermined extent equal to or more than 100 microns.

### BACKGROUND OF THE INVENTION

1. Field of the Invention

The present invention relates to an electronic device, electronic device producing method, thermal head, and thermal head producing method. More particularly, the present invention relates to an electronic device and electronic device producing method in which a layer with risk of corrosion is formed, and influence of occurrence of corrosion can be suppressed reliably, and also to a thermal head, and thermal head producing method

2. Description Related to the Prior Art

Various attempts have been made to reduce the manufacturing cost of a thermal head for use in a thermal printer of any of plural types. A large area plate workpiece with a multiple pattern of circuits is prepared, and separated by cutting to obtain a number of circuit boards or bodies of the thermal head. To increase the number of the circuit boards available from the plate workpiece, it is conceivable to reduce the size of the circuit boards, to raise the density of integration.

JP-A 2002-046297 and 2005-007709 disclose suggestion for raising the density of integration. Common electrodes and individual electrodes are formed on a first side of the resistor as heating elements in forming the resistor and a aluminum electrode layer on a partial glaze. Return electrodes are formed on a second side of the resistor as heating elements, and opposed to the common electrodes and individual electrodes. This is effective because of no need of forming the common electrodes with a large area on any one of the first and second side, so that the density of integration can be higher.

A method of dicing is known, in which a diamond blade with a thickness of 50-300 microns is rotated at a high speed to cut the plate workpiece accurately into the circuit boards or bodies of the thermal head. A distance from a top of the partial glaze to an end face of the plate workpiece can be set short, to reduce the size of the thermal head.

The aluminum electrode layer characteristically has risk of corrosion. A portion of the aluminum electrode layer appears on a cut end face of the circuit board or body of the thermal head after dicing or cutting. Corrosion with time is likely to occur on the aluminum electrode layer, to cause partial peeling of a protective layer which is disposed to cover the aluminum electrode layer and extends to the cut end face. A suggestion to prevent the partial peeling of the protective layer is to position the aluminum electrode layer farther from the cut end face so as to prevent the aluminum electrode layer from appearing on the cut end face. However, cutting in the region where the partial glaze is adjacent to the protective layer by positioning the aluminum electrode layer farther from the cut end face causes chipping in the vicinity of the cut end face. It has been known that the chipping is derived by low strength in the adhesion between the partial glaze and the protective layer of which a widely used example is silicon nitride. The partial peeling is quickened with time by the chipping occurring at the cut end face at the time of cutting, to lower the yield of production of the circuit boards. To prevent occurrence of the chipping, it is conceivable to determine the position of the cut end face at a distance from the circuit board for the purpose of keeping the circuit board free from influence of the chipping after cutting. However, a required space between the circuit board and the cut end face is larger, to reduce the number of the circuit boards available from the thermal head. No effect for the cost reduction will be expected.

Also, it is known to position the aluminum electrode layer between the protective layer and the partial glaze for strengthening adhesion between the protective layer and the partial glaze. In view of quality, the forming of the aluminum electrode layer between the protective layer and the partial glaze in the circuit board or body of the thermal head is advantageous in cutting the plate workpiece, because the chipping can be prevented owing to the use of the tightly adhering regions to be cut. However, there is a problem in that portions of the aluminum electrode layer appear on the cut end face diced to obtain the circuit board from the plate workpiece. Corrosion of the aluminum electrode layer is likely to occur on the cut end face. No known technique can solve this problem reliably. For example, a surplus portion of the protective layer may be formed to cover the cut end face of the circuit board for prevent the aluminum electrode layer from corrosion in the uncovered state on the cut end face. However, the forming of the surplus portion of the protective layer requires the increase of the number of the producing steps. The operation of production will be further complicated. Fine dust is likely to stick on the cut end face in forming the protective layer, and will lower the yield of the production due to possible increase in defects of the protective layer.

### SUMMARY OF THE INVENTION

In view of the foregoing problems, an object of the present invention is to provide an electronic device and electronic device producing method in which a layer with risk of corrosion is formed, and influence of occurrence of corrosion can be suppressed reliably, and also to a thermal head, and thermal head producing method

In order to achieve the above and other objects and advantages of this invention, an electronic device producing method is provided, an electronic device having a circuit pattern. The electronic device includes a substrate, on which the circuit pattern is formed, and which is obtained by cutting a plate workpiece along a cut line for respectively the circuit pattern. In the electronic device producing method, a spot pattern is formed on a first layer of a material with risk of corrosion, the spot pattern including plural spot regions arranged on the plate workpiece in a two-dimensional manner, wherein the spot pattern is cut along the cut line to cause the first layer to appear on a cut end face of the cut line.

The spot pattern extends toward the circuit pattern from the cut end face at a predetermined extent equal to or more than 100 microns.

Each of the spot regions has a width equal to or more than 20 microns and equal to or less than 30 microns.

The substrate is further overlaid with a protection film, and the first layer contacts the protection film, and strengthens adhesion between the substrate and the protection film.

A plurality of the substrate are arranged on the plate workpiece in a substrate train, and include a first substrate and a second substrate adjacent to the first substrate, and oriented in reverse thereto.

A plurality of the substrate are arranged in a matrix form on the plate workpiece.

Also, an electronic device having a circuit pattern includes a substrate, on which the circuit pattern is formed, and which is obtained by cutting a plate workpiece along a cut line for respectively the circuit pattern. A spot pattern is formed on a first layer of a material with risk of corrosion, includes plural spot regions arranged on the plate workpiece in a two-dimensional manner, and is cut along the cut line to cause the first layer to appear on a cut end face of the cut line.

Furthermore, a protection film protects the substrate and the circuit pattern. The first layer contacts the protection film, and strengthens adhesion between the substrate and the protection film.

Specifically, a thermal head producing method is provided, a thermal head including a substrate, a partial glaze, a resistor layer and an aluminum electrode layer overlaid on one another sequentially, and a protective layer for protecting the electrode layer and the resistor layer, wherein the substrate is obtained by cutting a plate workpiece along a cut line for respectively the electrode layer and the resistor layer. In the thermal head producing method, a spot pattern is formed on the electrode layer, the spot pattern including plural spot regions arranged on the plate workpiece in a two-dimensional manner, wherein the spot pattern is cut along the cut line to cause the electrode layer to appear on a cut end face of the cut line.

The electrode layer is patterned on the resistor layer to form an individual electrode, a common electrode and a return electrode, the individual and common electrodes being disposed on a first side and alternately with one another, the return electrode being disposed on a second side opposite to the first side.

A surplus electrode form is disposed between the spot pattern and the return electrode, and constituted by a shape of the electrode layer extending with a solid surface.

A plurality of the substrate are arranged on the plate workpiece in a substrate train, and include a first substrate and a second substrate adjacent to the first substrate, and oriented in reverse thereto, and the cut line lies between a plurality of the return electrode.

The electrode layer is patterned on the resistor layer to form an individual electrode and a common electrode on sides opposite to one another.

A surplus electrode form is disposed between the spot pattern and the common electrode, and constituted by a shape of the electrode layer extending with a solid surface.

A plurality of the substrate are arranged on the plate workpiece in a substrate train, and include a first substrate and a second substrate adjacent to the first substrate, and oriented in reverse thereto, and the cut line lies between a plurality of the common electrode.

A thermal head includes a substrate, a partial glaze, a resistor layer and an aluminum electrode layer overlaid on one another sequentially. A protective layer protects the electrode layer and the resistor layer. The substrate is obtained by cutting a plate workpiece along a cut line for respectively the electrode layer and the resistor layer. A spot pattern is formed on the electrode layer, includes plural spot regions arranged on the plate workpiece in a two-dimensional manner, and is cut along the cut line to cause the electrode layer to appear on a cut end face of the cut line.

### BRIEF DESCRIPTION OF THE DRAWINGS

The above objects and advantages of the present invention will become more apparent from the following detailed description when read in connection with the accompanying drawings, in which:

FIG. 1 is a cross section, partially broken, illustrating a thermal head in a thermal printer;

FIG. 2 is a plan, partially broken, illustrating a plate workpiece to produce the thermal head;

FIG. 3A is a plan, partially broken, illustrating portions of the plate workpiece to be cut;

FIG. 3B is a vertical section, partially broken, taken on line IIIB-IIIB, illustrating the plate workpiece of circuit boards;

FIG. 4 is a plan illustrating overall arrangement of the plate workpiece;

FIG. 5 is a plan, partially broken, illustrating portion of another preferred plate workpiece of circuit boards for a thermal head;

FIG. 6 is a plan illustrating the plate workpiece; and

FIG. 7 is a plan, partially broken, illustrating portion of the plate workpiece of circuit boards of FIG. 6.

### DETAILED DESCRIPTION OF THE PREFERRED EMBODIMENT(S) OF THE PRESENT INVENTION

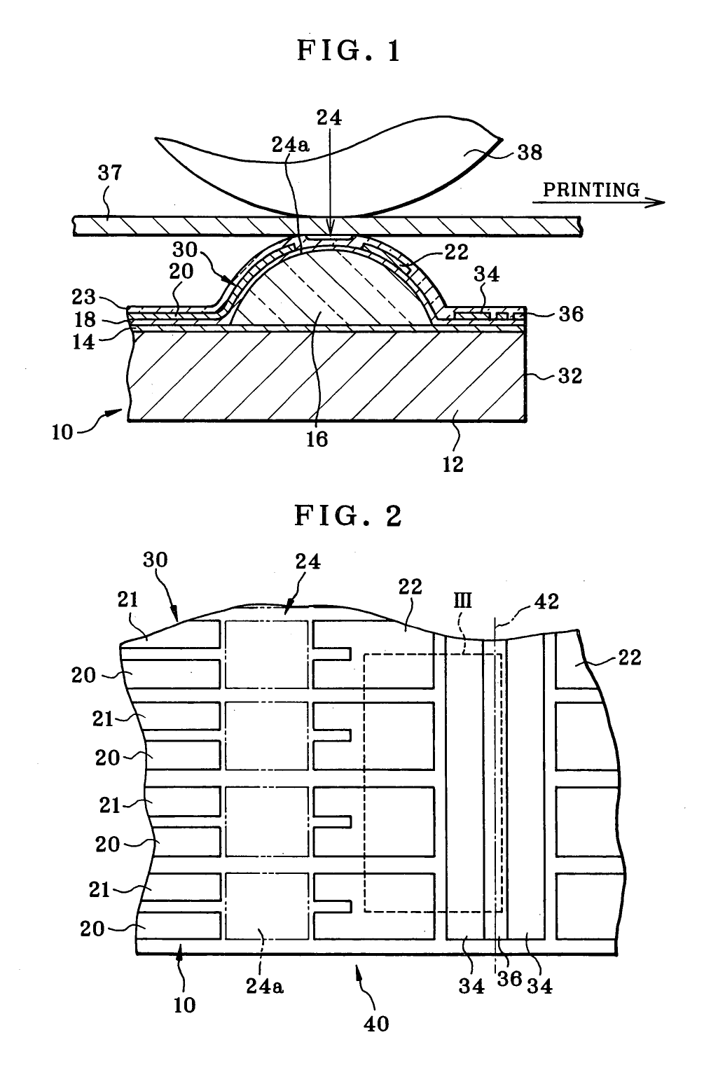

In FIG. 1 as a section, a thermal head 10 with a thermal head body in an electronic device includes a substrate 12 of aluminum oxide, a glaze 14, a partial glaze 16, a resistor layer 18, an aluminum electrode layer, and a protective layer 23 overlaid sequentially. The aluminum electrode layer is formed on the resistor layer 18 in a form of an individual electrode layer 20 of aluminum, a common electrode layer 21 of aluminum (See FIG. 2), and a return electrode portion 22. The protective layer 23 covers the resistor layer 18 and the individual, common and return electrodes 20-22. The glaze 14 and the partial glaze 16 are formed from material characteristically accumulating heat. Examples of the materials include glass of which a main component is silicon dioxide, synthetic resin, and the like. To produce the individual, common and return electrodes 20-22, the resistor layer 18 is overlaid with an aluminum electrode layer, which is masked and etched, to pattern the electrode layer. A heating region 24a is defined by each portion of the resistor between the individual electrode layer 20, the common electrode layer 21 and the return electrode portion 22. Heating elements 24 are constituted by the resistor layer 18 and the individual, common and return electrodes 20-22. Note that a term of an internal circuit pattern 30 is used to refer to patterned electrodes including the individual electrode layer 20, the common electrode layer 21 and the return electrode portion 22.

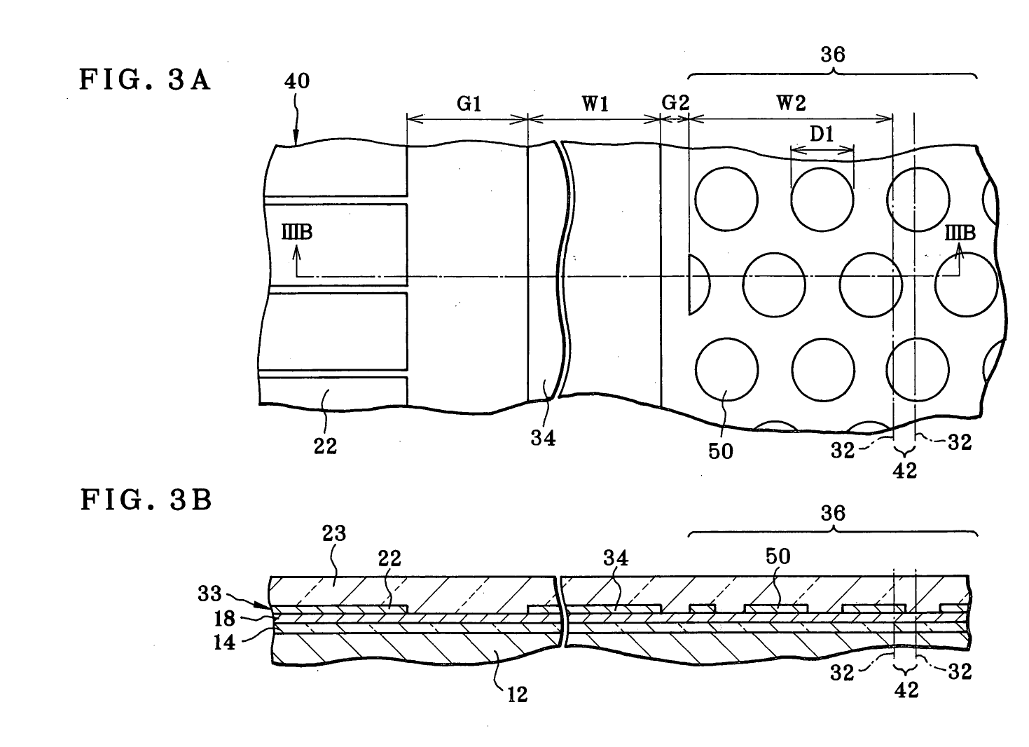

In FIGS. 1 and 3, a cut end face 32 lies at an end of the partial glaze 16 of the thermal head 10 in the printing direction. A dummy electrode portion or surplus electrode form 34, and a spot pattern 36 or island shaped pattern are disposed between the cut end face 32 and the partial glaze 16. The surplus electrode form 34 is a portion of an electrode layer 33 of aluminum extending with a solid surface. The spot pattern 36 is formed on and near to the cut end face 32 as an end face of the thermal head 10. The surplus electrode form 34 is disposed between the spot pattern 36 and the internal circuit pattern 30. Also, the protective layer 23 covers the surplus electrode form 34 and the spot pattern 36.

A platen roller 38 is opposed to the thermal head 10. A recording sheet 37 or material is squeezed between the thermal head 10 and the platen roller 38 and transported in the direction of the arrow for printing. When the individual electrode layer 20 and the common electrode layer 21 are supplied with electric current, the heating region 24a in the resistor layer 18 are caused by the return electrode portion 22 to generate heat. Power for the heating elements 24 is controlled, to record a pixel at a gradation level or density by coloring of the recording sheet 37. The position or size of the heating elements 24 is determined suitably according to pixel density, pressure of contact of the thermal head 10, a radius of curvature of the partial glaze 16 and a diameter of the platen roller 38.

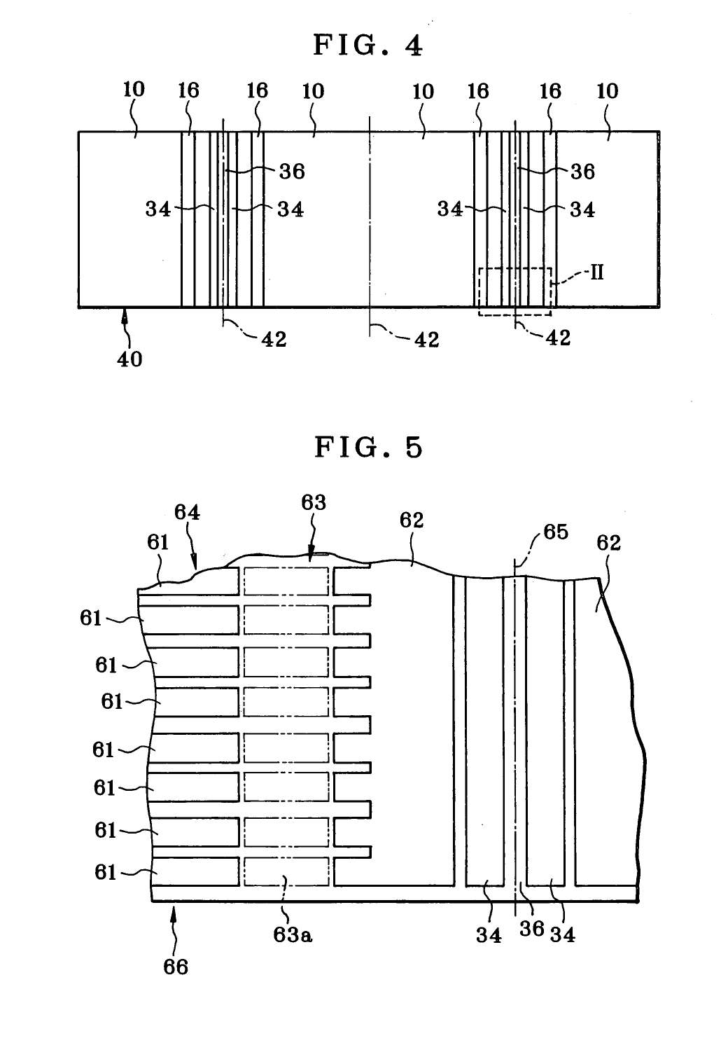

In FIG. 4, A large area plate workpiece 40 for multiple production of circuit boards or thermal head is viewed in a plan. FIG. 2 is a plan in enlargement for the portion II near to three cut lines 42. Four thermal heads 10 are arranged on the plate workpiece 40 in FIG. 4. Along the cut lines 42, the plate workpiece 40 is cut, to obtain the four thermal heads 10. To increase the number of the thermal head 10 obtainable from the plate workpiece 40, the return electrode portions 22 on the partial glaze 16 are disposed on the plate workpiece 40 to face on one another with respect to the cut lines 42. The spot pattern 36 is formed on the cut lines 42 where the return electrode portions 22 are opposed to one another. The surplus electrode form 34 is shaped beside the spot pattern 36.

In FIG. 3A, a portion III in FIG. 2 is illustrated in enlargement. FIG. 3B is a section taken on line IIIB-IIIB of FIG. 3A. A process of board production of FIGS. 3A and 3B is described. At first, the substrate 12 is overlaid with the glaze 14, the partial glaze 16 (See FIG. 1), the resistor layer 18 and the electrode layer 33 one after another. Then the plate workpiece 40 is etched to form various portions of the thermal head 10, including the internal circuit pattern 30 with the individual electrode layer 20, the common electrode layer 21 and the return electrode portion 22, and the surplus electrode form 34 and the spot pattern 36. Finally, the plate workpiece 40 is covered with the protective layer 23 after forming the internal circuit pattern 30.

A great number of circles or patterned spot regions 50 or island regions are disposed in the spot pattern 36 and distributed at a suitable pitch. The spot pattern 36 is separate from the surplus electrode form 34 at a suitable distance. The return electrode portion 22 is separate from the surplus electrode form 34 at a suitable distance. The distance G1 between the surplus electrode form 34 and the return electrode portion 22 is 10 microns or more. A width W1 of the surplus electrode form 34 is 100 microns or more. The distance G2 between the surplus electrode form 34 and the spot pattern 36 is 10 microns or more. Preferably, a diameter D1 of the patterned spot regions 50 is 20-30 microns. A ratio of the area of the patterned spot regions 50 to the area of the total quadrilateral region with the spot pattern 36 is preferably 50%. A distance W2 from the cut end face 32 to the spot pattern 36 after cutting with the cut lines 42 is 100 microns or more.

The operation of the embodiment is described. In FIG. 2, the cut lines 42 are determined to run across the spot pattern 36 of the plate workpiece 40 so as to set the distance W2 equal to or more than 100 microns, the distance W2 being defined between the cut end face 32 and the spot pattern 36. The plate workpiece 40 is cut along the cut lines 42. After the cutting, a section of the spot pattern 36 appears on the end of the cut end face 32. A region of the section includes a first domain where a side of the patterned spot regions 50 in the spot pattern 36 appears, and a second domain without presence of the patterned spot regions 50.

In the region of the cut end face 32 where an end face of the patterned spot regions 50 appears, the portion of the patterned spot regions 50 corrodes on the cut end face 32 due to the lack of the structure for the anti corrosion. However, the patterned spot regions 50 are not connected with the return electrode portion 22 in the internal circuit pattern 30 or the surplus electrode form 34, development of the corrosion on the cut end face can be suppressed within the patterned spot regions 50. Also, an area of the exposed portion of the patterned spot regions 50 on the cut end face 32 is much smaller than the area of the surplus electrode form 34, and the area of the internal circuit pattern 30 where the protective layer 23 and the glaze 14 are stuck strongly, and the area of the inner portion of the patterned spot regions 50. Partial peeling of the protective layer can be suppressed in the patterned spot regions 50 even upon occurrence of the corrosion. Thus, the form of the patterned spot regions 50 on the cut end face 32 is effective in minimizing the corrosion of the electrode layer 33, and minimizing the partial peeling of the protective layer of the thermal head 10.

In a part of the cut end face 32 without presence of the patterned spot regions 50, the protective layer 23 adheres to the glaze 14 at a small strength in the vicinity of the cut end face 32. Chipping is likely to occur upon the cutting, to cause partial peeling of the protective layer 23. However, the patterned spot regions 50 in the thermal head 10 and the surplus electrode form 34 keep adhesion tight between the protective layer 23 and the glaze 14. So chipping can be suppressed on the cut end face. No extension of the partial peeling of the protective layer 23 occurs to the surplus electrode form 34.

This being so, the cut line 42 is so defined on the plate workpiece 40 to run across the spot pattern 36 as to form a partial shape of the spot pattern 36 on the cut end face 32 at an intended width after cutting. This is effective in minimizing corrosion of the electrode layer 33 in the thermal head 10. Also, the spot pattern 36 of the electrode layer 33 tightens the adhesion between the protective layer 23 and the substrate 12 in the vicinity of the cut end face 32. Occurrence of chipping near to the cut end face 32 can be suppressed, to raise yield of the production. A cost of the thermal head can be reduced. Furthermore, the surplus electrode form 34 tightens the adhesion between the protective layer 23 and the substrate 12. Supply of the thermal head 10 can be possible with reliability at a reduced cost.

As chipping on the cut end face 32 can be suppressed, various cutting methods such as dicing can be used. Note that, on the plate workpiece 40, regions for the thermal head 10 are so disposed that the return electrode portions 22 are opposed to one another. The cut line 42 is positioned between a first one of the return electrode portions 22 and a second one of the return electrode portions 22 opposed to the first. This is effective in raising the number of the thermal head 10 available from the plate workpiece 40. A cost of manufacturing the thermal head 10 can be reduced.

In the above embodiment, cutting of the thermal head 10 from the plate workpiece 40 for the purpose of production is described. However, cutting according to the invention can be for the purpose of abandonment. Waste circuit boards or large plate workpiece can be broken into pieces by cutting of the invention.

Dicing is used to cut out the thermal head 10. However, other cutting methods can be used. For example, a groove to reduce a thickness, or a train of perforations, can be formed in the plate workpiece. The plate workpiece can be broken into the thermal head 10 according to a breaking method. Also, a cutting blade and abrasion agent can be used for cutting.

In the above embodiment, the electrode layer 33 is an example of material to form the surplus electrode form 34 and the spot pattern 36. However, other material can be used for reinforcing strength in adhesion between the protective layer 23 and the glaze 14.

It is possible to set a distance from the top of the partial glaze 16 to the cut end face 32 smaller than that according to known technique. It is possible to remove interference between a downstream flat portion and the recording material in the thermal head of the direct recording type. A surface of the recording material after printing can be smooth with higher gloss. Furthermore, the thermal head of the invention may be a printhead in the thermal recording of wax transfer type or heat sublimation type.

In the above embodiment, the resistor layer 18 is formed in a region without the pattern. However, it is possible to eliminate part of the resistor layer 18 in an unpatterned region by etching.

In the above embodiment, the thermal head 10 has the partial glaze 16. However, a thermal head of the invention may have other layered structure, and can have a flat glaze or the like.

In the above embodiment, the distance G1 is defined between the surplus electrode form 34 and the return electrode portion 22. However, the distance G1 may be defined between the surplus electrode form 34 and the internal circuit pattern 30 according to the invention.

The patterned spot regions 50 may have any suitable shape, and can be not only circular but polygonal, elliptical or the like.

Despite the thermal head 10 of the FIG. 2 with the return electrode portion 22, a thermal head 64 as an electronic device of the invention can have a construction of FIG. 5. The thermal head 64 includes an individual electrode layer 61 of aluminum, a common electrode layer 62 of aluminum, and heating elements 63. A heating region 63a is defined by each portion between the individual electrode layer 61 and the common electrode layer 62 to constitute the heating elements 63. A large area plate workpiece 66 for multiple production of circuit boards or thermal head is prepared. The plate workpiece 66 has cut lines 65 with respect of which regions of the common electrode layer 62 are disposed and opposed to one another. The surplus electrode form 34 is formed beside the spot pattern 36. It is possible to cut the plate workpiece 66 into the thermal head 64 by separating along the cut lines 65.

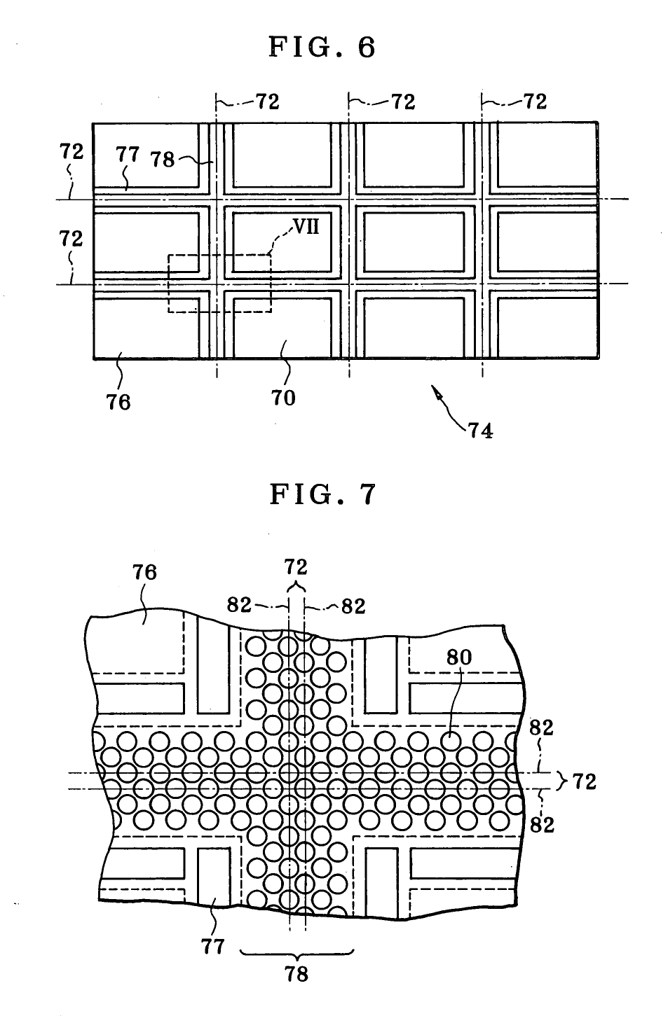

A still another preferred embodiment is described by referring to FIG. 6. A large area plate workpiece 74 for multiple production of circuit boards is depicted in FIG. 6 in a plan. There are cut lines 72. Plural electronic devices 70 are cut out of the plate workpiece 74 by cutting along the cut lines 72. 12 circuit regions 76 are defined in the plate workpiece 74 of FIG. 6. The electronic device 70 is obtained from each of the circuit regions 76. A pattern and insulation layer are formed inside the circuit regions 76 from material with risk of corrosion in contact with air, such as aluminum, copper or the like in the electronic device 70. Also, a protection film is formed to cover the pattern and insulation layer, and has weak adhesion to the plate workpiece 74.

A dummy electrode portion or surplus electrode form 77 is formed on the periphery of the circuit regions 76, and constituted by a portion of the electrode layer extending with a solid surface. A spot pattern 78 or island shaped pattern is disposed about the surplus electrode form 77. Examples of materials of the surplus electrode form 77 and the spot pattern 78 include aluminum, copper and the like. Adhesion between the plate workpiece 74 and the protective layer can be tightened. Corrosion may occur if one of those appears on the cut end face. However, corrosion further than the spot pattern 78 is suppressed. Partial peeling of the protective layer can be prevented.

In FIG. 7, a portion VII in FIG. 6 is illustrated in enlargement. Numerous patterned spot regions or island regions 80 are included in the spot pattern 78 of the material with risk of corrosion. A ratio of the area of the patterned spot regions 80 to the area of the total region with the spot pattern 78 is predetermined suitably. In the spot pattern 78, a distance between the patterned spot regions 80 and other near patterns should be sufficiently large irrespective of differences in the material, costs and producing methods. This is for the purpose of stabilizing forming of the patterned spot regions 80, separating the patterned spot regions 80 from the internal pattern in the electronic device 70. Also, a portion of the patterned spot regions 80 appears in a cut end face 82 after cutting the electronic device 70 should be free from transition of corrosion to other patterns. Also, the cut lines 72 can be preferably selected so as to form the spot pattern 78 with a suitable width in the vicinity of the cut end face 82 of the electronic devices 70 cut from the plate workpiece 74.

The operation of the third embodiment is described now. The cut lines 72 are selected on the plate workpiece 74 according to the above condition, to cut out the electronic devices 70 in a plural number. A portion of the patterned spot regions 80 which appears on the cut end face 82 of the electronic devices 70 after being cut is likely to corrode in contact with air or atmosphere. However, a sufficient distance exists between the patterned spot regions 80 and other patterns beside the patterned spot regions 80. Corrosion created from the patterned spot regions 80 does not develop to a portion of the internal pattern, but is prevented from propagation in the patterned spot regions 80. No influence of corrosion of the cut end face 82 to the internal pattern occurs, although no structure for anti corrosion is made on the cut end face 82. Because the surplus electrode form 77 and the spot pattern 78 are formed near to the cut lines 72 from material to reinforce adhesion between the plate workpiece 74 and the protective layer, it is possible to prevent occurrence of partial peeling or defects of protective layer due to stress in the plate workpiece 74 in the course of cutting the plate workpiece 74.

Accordingly, the cut lines 72 are so defined on the plate workpiece 74 to run across the spot pattern 78 as to form a partial shape of the spot pattern 78 on the cut end face 82 at an intended width after cutting. This is effective in minimizing corrosion of the electrode layer in the electronic device 70. Also, the spot pattern 78 of the electrode layer tightens the adhesion between the protective layer 23 and the substrate 12 in the vicinity of the cut end face 82. Occurrence of chipping near to the cut end face 82 can be suppressed, to raise yield of the production. A cost of the electronic devices 70 can be reduced. Dicing for cutting, which may cause stress in the board, can be utilized. The number of the boards available from the plate workpiece 74 can be higher. Supply of the electronic devices 70 can be possible with reliability at a reduced cost.

In the embodiment, the surplus electrode form 77 is shaped about the circuit regions 76. However, the plate workpiece 74 without the surplus electrode form 77 can be used in the present invention, in particular if the adhesion between the plate workpiece 74 and the protective layer is strong enough, or in case of lack of the protective layer.

In the above embodiment, the plate workpiece 74 is used for producing an electronic device. However, a printed board or other plastic board may be produced according to the invention. The feature of the invention is effective in forming a reinforcing layer between a substrate and a protective layer, the reinforcing layer having risk of corrosion in contact with air.

Although the present invention has been fully described by way of the preferred embodiments thereof with reference to the accompanying drawings, various changes and modifications will be apparent to those having skill in this field. Therefore, unless otherwise these changes and modifications depart from the scope of the present invention, they should be construed as included therein.

What is claimed is:

1. An electronic device producing method of producing an electronic device which has a circuit pattern, and includes a substrate, on which said circuit pattern is formed, and which is obtained by cutting a plate workpiece along a cut line for respectively said circuit pattern, said electronic device producing method comprising a step of:
forming a spot pattern on a first layer of a material with risk of corrosion, said spot pattern including plural spot regions arranged on said plate workpiece in a two-dimensional manner, wherein said spot pattern is cut along said cut line to cause said first layer to appear on a cut end face of said cut line.

2. An electronic device producing method as defined in claim 1, wherein said spot pattern extends toward said circuit pattern from said cut end face at a predetermined extent equal to or more than 100 microns.

3. An electronic device producing method as defined in claim 2, wherein each of said spot regions has a width equal to or more than 20 microns and equal to or less than 30 microns.

4. An electronic device producing method as defined in claim 1, wherein said substrate is further overlaid with a protection film, and said first layer contacts said protection film, and strengthens adhesion between said substrate and said protection film.

5. An electronic device producing method as defined in claim 4, wherein a plurality of said substrate are arranged on said plate workpiece in a substrate train, and include a first substrate and a second substrate adjacent to said first substrate, and oriented in reverse thereto.

6. An electronic device producing method as defined in claim 4, wherein a plurality of said substrate are arranged in a matrix form on said plate workpiece.

7. An electronic device having a circuit pattern, comprising:
a substrate, on which said circuit pattern is formed, and which is obtained by cutting a plate workpiece along a cut line for respectively said circuit pattern;
a spot pattern, being formed on a first layer of a material with risk of corrosion, including plural spot regions arranged on said plate workpiece in a two-dimensional manner, and being cut along said cut line to cause said first layer to appear on a cut end face of said cut line.

8. An electronic device as defined in claim 7, wherein said spot pattern extends toward said circuit pattern from said cut end face at a predetermined extent equal to or more than 100 microns.

9. An electronic device as defined in claim 8, wherein each of said spot regions has a width equal to or more than 20 microns and equal to or less than 30 microns.

10. An electronic device as defined in claim 8, further comprising a protection film for protecting said substrate and said circuit pattern;
wherein said first layer contacts said protection film, and strengthens adhesion between said substrate and said protection film.

11. A thermal head producing method of producing a thermal head including a substrate, a partial glaze, a resistor layer and an aluminum electrode layer overlaid on one another sequentially, and a protective layer for protecting said electrode layer and said resistor layer, wherein said substrate is obtained by cutting a plate workpiece along a cut line for respectively said electrode layer and said resistor layer, said thermal head producing method comprising a step of:
forming a spot pattern on said electrode layer, said spot pattern including plural spot regions arranged on said plate workpiece in a two-dimensional manner, wherein said spot pattern is cut along said cut line to cause said electrode layer to appear on a cut end face of said cut line.

12. A thermal head producing method as defined in claim 11, wherein said spot pattern extends toward an electrode position of said electrode layer from said cut end face at a predetermined extent equal to or more than 100 microns.

13. A thermal head producing method as defined in claim 11, wherein said electrode layer is patterned on said resistor layer to form an individual electrode, a common electrode and a return electrode, said individual and common electrodes being disposed on a first side and alternately with one another, said return electrode being disposed on a second side opposite to said first side.

14. A thermal head producing method as defined in claim 13, wherein a surplus electrode form is disposed between said spot pattern and said return electrode, and constituted by a shape of said electrode layer extending with a solid surface.

15. A thermal head producing method as defined in claim 14, wherein a plurality of said substrate are arranged on said plate workpiece in a substrate train, and include a first substrate and a second substrate adjacent to said first substrate, and oriented in reverse thereto, and said cut line lies between a plurality of said return electrode.

16. A thermal head producing method as defined in claim 11, wherein said electrode layer is patterned on said resistor layer to form an individual electrode and a common electrode on sides opposite to one another.

17. A thermal head producing method as defined in claim 16, wherein a surplus electrode form is disposed between said spot pattern and said common electrode, and constituted by a shape of said electrode layer extending with a solid surface.

18. A thermal head producing method as defined in claim 17, wherein a plurality of said substrate are arranged on said plate workpiece in a substrate train, and include a first substrate and a second substrate adjacent to said first substrate, and oriented in reverse thereto, and said cut line lies between a plurality of said common electrode.

19. A thermal head comprising:
a substrate, a partial glaze, a resistor layer and an aluminum electrode layer overlaid on one another sequentially;
a protective layer for protecting said electrode layer and said resistor layer;
wherein said substrate is obtained by cutting a plate workpiece along a cut line for respectively said electrode layer and said resistor layer;
a spot pattern being formed on said electrode layer, including plural spot regions arranged on said plate workpiece in a two-dimensional manner, and being cut along said cut line to cause said electrode layer to appear on a cut end face of said cut line.

20. A thermal head as defined in claim 19, wherein said spot pattern extends toward an electrode position of said electrode layer from said cut end face at a predetermined extent equal to or more than 100 microns.

21. A thermal head as defined in claim 19, wherein said electrode layer is patterned on said resistor layer to form an individual electrode, a common electrode and a return electrode, said individual and common electrodes being disposed on a first side and alternately with one another, said return electrode being disposed on a second side opposite to said first side.

22. A thermal head as defined in claim 21, further comprising a surplus electrode form disposed between said spot pattern and said return electrode, and constituted by a shape of said electrode layer extending with a solid surface.

23. A thermal head as defined in claim 19, wherein said electrode layer is patterned on said resistor layer to form an individual electrode and a common electrode on sides opposite to one another.

24. A thermal head as defined in claim 23, further comprising a surplus electrode form disposed between said spot pattern and said common electrode, and constituted by a shape of said electrode layer extending with a solid surface.
